(19) United States
(12) Patent Application Publication
(10) Pub. No.: US 2011/0227061 A1
(43) Pub. Date: Sep. 22, 2011

(54) SEMICONDUCTOR OXIDE NANOFIBER-NANOROD HYBRID STRUCTURE AND ENVIRONMENTAL GAS SENSOR USING THE SAME

(75) Inventors: Su Jae Lee, Daejeon (KR); Chae Ryong Cho, Gyeongsangnam-do (KR)

(73) Assignees: ELECTRONICS AND TELECOMMUNICATIONS RESEARCH INSTITUTE, Daejeon (KR); INSTITUTE FOR RESEARCH AND INDUSTRY COOPERATION PUSAN NATIONAL UNIVERSITY, Busan (KR)

(21) Appl. No.: 12/948,022

(22) Filed: Nov. 17, 2010

(30) Foreign Application Priority Data
Mar. 17, 2010 (KR) 10-2010-0023616

(51) Int. Cl. H01L 29/12; H01L 21/64; B82Y 99/00; B82Y 40/00

(52) U.S. Cl. 257/43; 438/49; 257/E29.068; 257/E21.001; 977/812; 977/811; 977/890

(57) ABSTRACT

Provided is an environmental gas sensor including an insulating substrate, a metal electrode formed above the insulating substrate, and a sensing layer formed of a semiconductor oxide nanofiber-nanorod hybrid structure above the metal electrode. The environmental gas sensor can have excellent characteristics of ultra high sensitivity, high selectivity, high responsiveness and low power consumption by forming a semiconductor oxide nanorod having high sensitivity to a specific gas on a semiconductor oxide nanofiber.

### CROSS-REFERENCE TO RELATED APPLICATION

This application claims priority to and the benefit of Korean Patent Application No. 10-2010-0023616, filed Mar. 17, 2010, the disclosure of which is incorporated herein by reference in its entirety.

### BACKGROUND

1. Field of the Invention

The present invention relates to an environmental gas sensor, and more particularly, to an environmental gas sensor using a semiconductor oxide nanofiber-nanorod hybrid structure.

2. Discussion of Related Art

Semiconductor oxides for sensing a gas have been researched and developed to be manufactured in shapes of a bulk, a thick film, a chip, and a thin film due to excellent reactivity to a reactive gas, stability, endurance and productivity. Gas sensitivity to the reactive gas of the semiconductor oxide gas sensor is caused by the change in electrical characteristics of the semiconductor oxide by a reversible chemical reaction occurring when the reactive gas is adsorbed to or released from an oxide surface.

Improvements in gas sensitivity of the semiconductor oxide gas sensor are mainly focused on developing a semiconductor oxide material generally having high reactivity and improving a manufacturing process. Particularly, endeavors to manufacture a 2D or 3D semiconductor oxide thin film gas sensor having a high surface area-to-volume ratio and porosity using a crystallized oxide sensor material having several to several hundreds of nanometers are progressing. Various organic/inorganic fusing processes using a polymer template are being attempted.

However, new processes will be required to overcome fundamental structural problems that the semiconductor oxide thin film gas sensor has, for example, an interfacial reaction occurring between an insulating supporting substrate and an oxide for sensing gas and limits to an increase in reactive area. Thus, there have been attempts to manufacture a gas sensor using a 1D semiconductor oxide nano structure such as a nanorod, nanoribon, nanotube, or nanoparticle. Such a sensor based on the 1D oxide semiconductor nano structure has a larger specific surface area than the aforementioned bulk, thin film, and thick film sensors. Using such characteristics, an ultra-highly sensitive and functional sensor capable of sensing an environmentally harmful gas can be manufactured.

Particularly, recently, a nanofiber can be easily manufactured by electrospinning at a low price, and much research on developing an environmental gas sensor based on a semiconductor oxide nanofiber is being conducted. While much research on an environmental gas sensor based on a semiconductor oxide nanorod capable of being manufactured by a wet-chemical process is also in progress, the sensor cannot be developed on a commercial scale due to an increase in contact resistance between an electrode and a nanorod.

Accordingly, to develop an environmental gas sensor having ultra high sensitivity, high responsiveness, high selectivity, and high stability, it is necessarily required to develop a sensible material having a very large specific surface area.

### SUMMARY OF THE INVENTION

The present invention is directed to an environmental gas sensor having ultra high sensitivity, high responsiveness, high selectivity, and long-term stability using a semiconductor oxide nanofiber-nanorod hybrid structure having an extremely large surface area.

One aspect of the present invention provides a semiconductor oxide nanofiber-nanorod hybrid structure, including: a semiconductor oxide nanofiber; and a semiconductor oxide nanorod formed on the semiconductor oxide nanofiber.

In one embodiment, the semiconductor oxide nanofiber and the semiconductor oxide nanorod may be formed of different semiconductor oxides.

In the embodiment, the semiconductor oxide nanofiber may be formed of one selected from the group consisting of ABO₃-type perovskite oxides (BaTiO₃, metal doped BaTiO₃, SrTiO₃, and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, CO₃O₄, and Al₂O₃.

In the embodiment, the semiconductor oxide nanorod may be formed of one selected from the group consisting of ABO₃-type perovskite oxides (BaTiO₃, metal doped BaTiO₃, SrTiO₃, and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, CO₃O₄, and Al₂O₃.

In the embodiment, the semiconductor oxide nanofiber may have a diameter of 1 to 100 nm.

In the embodiment, the semiconductor oxide nanorod may have a diameter of 1 to 100 nm, and a length of 1 to 100 nm.

Another aspect of the present invention provides an environmental gas sensor, including: an insulating substrate; a metal electrode formed above the insulating substrate; and a sensing layer formed of a semiconductor oxide nanofiber-nanorod hybrid structure above the metal electrode.

In one embodiment, the insulating substrate may be a single crystalline oxide substrate, a ceramic substrate, a silicon semiconductor substrate, or a glass substrate.

In the embodiment, the insulating substrate may be formed of a material selected from the group consisting of Al₂O₃, MgO, SrTiO₃, quartz, and SiO₂/Si.

In another embodiment, the environmental gas sensor may further include an electrode pad formed above the insulating substrate using the same material as the metal electrode.

In the embodiment, the metal electrode may be formed of at least one selected from the group consisting of Pt, Pd, Ag, Au, Ti, Cr, Al, Cu, Sn, and In.

In the embodiment, the semiconductor oxide nanofiber-nanorod hybrid structure constituting the sensing layer may be formed of at least two selected from the group consisting of ABO₃-type perovskite oxides (BaTiO₃, metal doped BaTiO₃, SrTiO₃, and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, CO₃O₄, and Al₂O₃.

In the embodiment, the semiconductor oxide nanofiber may be manufactured on the insulating substrate having the metal electrode by electrospinning, and the semiconductor oxide nanorod may be manufactured by physical or chemical deposition.

In the embodiment, the semiconductor oxide nanofiber may have a diameter of 1 to 100 nm.

In the embodiment, the semiconductor oxide nanorod may have a diameter of 1 to 100 nm, and a length of 1 to 100 nm.

In another embodiment, the environmental gas sensor may further include a micro thin film heater formed at the same level as or on a bottom of the metal electrode.

Still another aspect of the present invention provides a method of manufacturing a semiconductor oxide nanofiber-nanorod hybrid structure, including: mixing a metal oxide precursor, a polymer and a solvent to prepare a composite solution; spinning the composite solution by electrospinning and thermally treating the resulting solution to form a semiconductor oxide nanofiber; and forming an oxide nanorod on the metal semiconductor oxide nanofiber by physical or chemical deposition.

In the embodiment, spinning the composite solution by electrospinning and thermally treating the resulting solution to form a semiconductor oxide nanofiber may include spinning the composite solution by electrospinning to form an oxide/polymer composite fiber; thermally treating the composite fiber to volatilize the solvent; and thermally treating the thermally-treated composite fiber again at a high temperature to form a semiconductor oxide nanofiber.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a scanning electron microscope (SEM) image of a semiconductor oxide nanofiber-nanorod hybrid structure according to the present invention;

FIG. 2 is a perspective view of an environmental gas sensor using a semiconductor oxide nanofiber-nanorod hybrid structure according to the present invention;

FIG. 3 is a flowchart illustrating a method of manufacturing a semiconductor oxide nanofiber-nanorod hybrid structure according to the present invention;

FIG. 4A is an SEM image of a surface of a semiconductor oxide ZnO nanofiber according to an exemplary embodiment of the present invention;

FIG. 4B is an SEM image of a surface of a semiconductor oxide ZnO nanofiber-nanorod hybrid structure according to an exemplary embodiment of the present invention;

FIG. 5 is a graph of X-ray diffraction patterns of the semiconductor oxide ZnO nanofiber and the semiconductor oxide ZnO nanofiber-nanorod hybrid structure according to the exemplary embodiment of the present invention;

FIG. 6 is a time versus sensitivity graph according to a working temperature of a NO₂ gas sensor using the semiconductor oxide ZnO nanofiber-nanorod hybrid structure according to the exemplary embodiment of the present invention;

FIG. 7 is a graph showing the change in sensitivity according to the working temperature of the NO₂ gas sensor using the semiconductor oxide ZnO nanofiber-nanorod hybrid structure according to the exemplary embodiment of the present invention;

FIG. 8 is a time versus sensitivity graph according to a NO₂ gas concentration of the NO₂ gas sensor using the semiconductor oxide ZnO nanofiber-nanorod hybrid structure according to the exemplary embodiment of the present invention; and

FIG. 9 is a graph showing the change in sensitivity according to a NO₂ gas concentration of the NO₂ gas sensor using the semiconductor oxide ZnO nanofiber-nanorod hybrid structure according to the exemplary embodiment of the present invention.

### DETAILED DESCRIPTION OF EXEMPLARY EMBODIMENTS

Hereinafter, exemplary embodiments of the present invention will be described in detail. However, the present invention is not limited to the embodiments disclosed below, but can be implemented in various forms. For clarity, a part that is not related to the description of the present invention will be omitted, and similar part will be represented by a similar reference mark throughout the specification.

Throughout the specification, when a part “includes” or “comprises” a component, the part may include, not remove, another element, unless otherwise defined. In addition, the term “part” or “unit” used herein means a unit processing at least one function or operation.

First, electrospinning used in a method of manufacturing a semiconductor oxide nanofiber according to the present invention will be described.

Electrospinning is a method of most simply and effectively manufacturing a nanofiber at a low price with high productivity. The method of manufacturing a nanofiber using electro spinning may include electrospinning a composite solution of a metal oxide precursor, a polymer and a solvent, and thermally treating the resultant composite solution. Such a metal oxide nanofiber manufactured as described above is an oxide ultrafine fiber formed of crystallized oxide, and has a diameter of several to several hundreds of nanometers and a length of several micrometers.

The semiconductor oxide nanofiber is rigid, and can provide far higher volume-to-surface area ratio and porosity than a thin film. A far finer nanofiber may be manufactured by simply adjusting process parameters, parts and devices. In other words, the method according to the present invention can make a diameter of the nanofiber close to the width of a depletion layer. Thus, the semiconductor oxide nanofiber may be applied as a new 1D gas sensor having high sensitivity to a very low concentration of a reactive gas, and high response and recovering speeds. It has been reported that a gas sensor formed of a TiO₂ nanofiber of the semiconductor oxide nanofiber manufactured by electrospinning exhibits high gas sensitivity to a PPB concentration of the reactive gas.

Hereinafter, the present invention will be described in further detail with reference to the accompanying drawings.

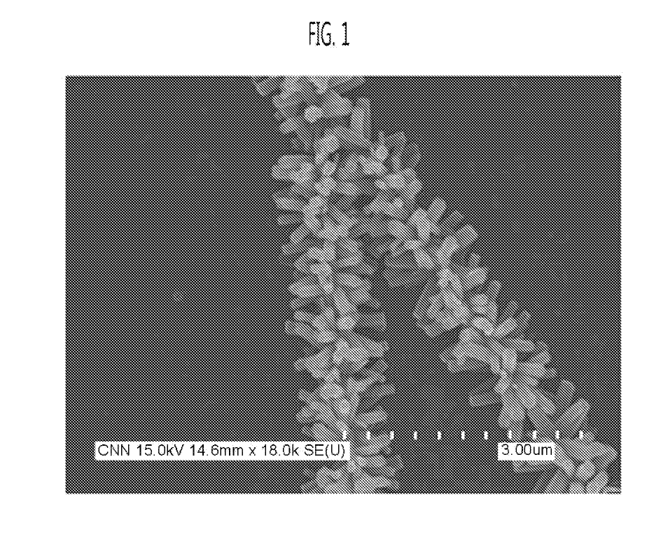

FIG. 1 is a scanning electronic microscope (SEM) image of a semiconductor oxide nanofiber-nanorod hybrid structure according to the present invention.

Referring to FIG. 1, the semiconductor oxide nanofiber-nanorod hybrid structure according to the present invention includes a semiconductor oxide nanofiber, and a semiconductor oxide nanorod formed on the semiconductor oxide nanofiber.

The semiconductor oxide nanofiber and the semiconductor oxide nanorod, which constitute the semiconductor oxide nanofiber-nanorod hybrid structure, may be formed of the same or different semiconductor oxides.

The semiconductor oxide nanofiber and nanorod may be formed of one selected from the group consisting of ABO₃-type perovskite oxides (BaTiO₃, metal doped BaTiO₃, SrTiO₃, and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, CO₃O₄, and Al₂O₃.

The semiconductor oxide nanofiber may be manufactured by electrospinning, and have a diameter of 1 to 100 nm.

The semiconductor oxide nanorod may be formed on the nanofiber by physical or chemical deposition (growth), and have a diameter of 1 to 100 nm and a length of 1 to 100 nm.

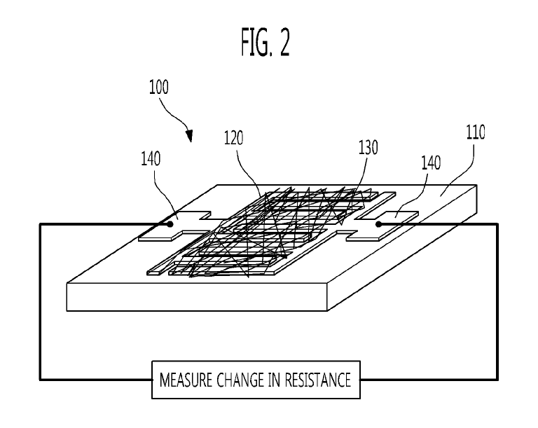

FIG. 2 is a perspective view of an environmental gas sensor using a semiconductor oxide nanofiber-nanorod hybrid structure according to the present invention.

Referring to FIG. 2, an environmental gas sensor 100 according to the present invention includes an insulating substrate 110, a metal electrode 120, and a sensing layer 130.

The insulating substrate 110 may be selected from the group consisting of a single crystalline oxide substrate, a ceramic substrate, a silicon semiconductor substrate to which an insulating layer is applied, and a glass substrate, which have a thickness of 0.1 to 1 mm.

The single crystalline oxide substrate may be formed of Al₂O₃, MgO or SrTiO₃, the ceramic substrate may be formed of Al₂O₃ or quartz, and the silicon semiconductor substrate may be formed of SiO₂/Si.

The metal electrode 120 is formed above the insulating substrate 110.

The metal electrode (e.g. Interdigital transducer metal electrode) 120 may be formed of one selected from the group consisting of Pt, Pd, Ag, Au, Ni, Ti, Cr, Al, and Cu, and have a thickness of 10 to 1000 nm.

The sensing layer 130 may be formed above the metal electrode 120, and formed of a semiconductor oxide nanofiber-nanorod hybrid structure.

The semiconductor oxide nanofiber-nanorod hybrid structure constituting the sensing layer 130 is the semiconductor oxide nanofiber-nanorod hybrid structure according to the present invention, and may include at least two of the same or different oxides selected from the group consisting of ABO₃-type perovskite oxides (BaTiO₃, metal doped BaTiO₃, SrTiO₃, and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, CO₃O₄, and Al₂O₃.

As described above, the semiconductor oxide nanofiber may be manufactured by spinning an oxide/polymer composite solution on the insulating substrate 110 having the metal electrode 120 by electrospinning, and thermally treating the resulting substrate at a high temperature of 500° C. or more, and may have a diameter of 1 to 100 nm.

The semiconductor oxide nanorod may be formed on the semiconductor oxide nanofiber to improve selectivity and responsiveness to a specific gas by physical or chemical deposition. The semiconductor oxide nanorod may have a diameter of 1 to 100 nm and a length of 1 to 100 nm.

The environmental gas sensor 100 according to the present invention may further include an electrode pad 140 and a micro thin film heater (not shown).

The electrode pad 140 may be formed of the same material as the metal electrode 120 above the insulating substrate 110.

While a basic structure excluding a micro thin film heater is illustrated in the present invention, the micro thin film heater may be formed on the same surface (above the insulating substrate 110) as a bottom of the metal electrode 120 (below the insulating substrate 110 and an opposite side of the metal electrode 120), or in (between the metal electrode 120 and the insulating substrate 110) the metal electrode 120.

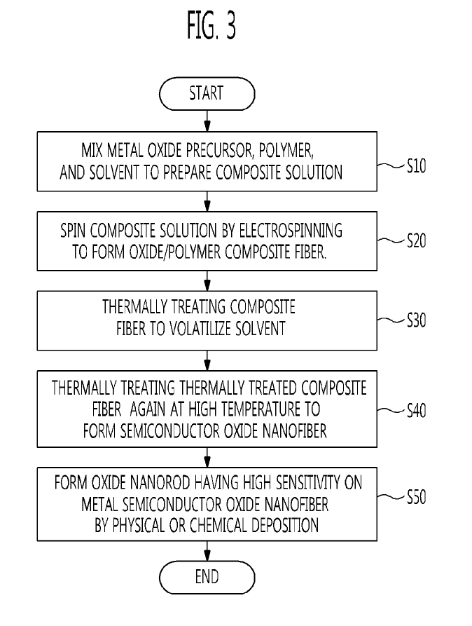

FIG. 3 is a flowchart illustrating a method of manufacturing a semiconductor oxide nanofiber-nanorod hybrid structure according to the present invention.

Referring to FIG. 3, the method of manufacturing a semiconductor oxide nanofiber-nanorod hybrid structure according to the present invention includes mixing a metal oxide precursor, a polymer, and a solvent to prepare a composite solution (S10).

Then, the composite solution is spun by electrospinning, and thermally treated to form a semiconductor oxide nanofiber.

In detail, the method includes spinning the composite solution by electrospinning to form an oxide/polymer composite fiber (S20), thermally treating the composite fiber to volatilize the solvent (S30), and thermally treating the thermally treated composite fiber again at a high temperature to form the semiconductor oxide nanofiber (S40).

Finally, an oxide nanorod having high sensitivity is formed on the metal semiconductor oxide nanofiber by physical or chemical deposition (S50).

The semiconductor oxide nanofiber-nanorod hybrid structure manufactured as described above is disposed on an insulating substrate having an electrode as a gas sensing layer, and thus an environmental gas sensor according to the present invention can be manufactured.

Hereinafter, the present invention will be described in detail with reference to an example which, however, is not provided to limit the present invention.

### Example

### Environmental Gas Sensor using Semiconductor Oxide Nanofiber-Nanorod Hybrid Structure

\textcircled{1} A metal oxide ZnO precursor, a poly(4-vinyl phenol) (PVP) polymer, and ethyl alcohol were weighed at a predetermined weight ratio and mixed. The mixed solution was stirred at 70° C. for 5 to 12 hours, thereby preparing a ZnO/PVP composite solution having a viscosity of 1200 CP.

\textcircled{2} The ZnO/PVP polymer composite solution was spun by electrospinning, thereby preparing a ZnO/PVP polymer composite fiber on a substrate having an electrode.

\textcircled{3} The ZnO/PVP composite fiber was thermally treated at 600° C., thereby obtaining a semiconductor oxide ZnO nanofiber.

\textcircled{4} A ZnO nanorod was formed on the semiconductor oxide ZnO nanofiber by chemical bath deposition (CBD), thereby preparing a ZnO nanofiber-nanorod hybrid structure.

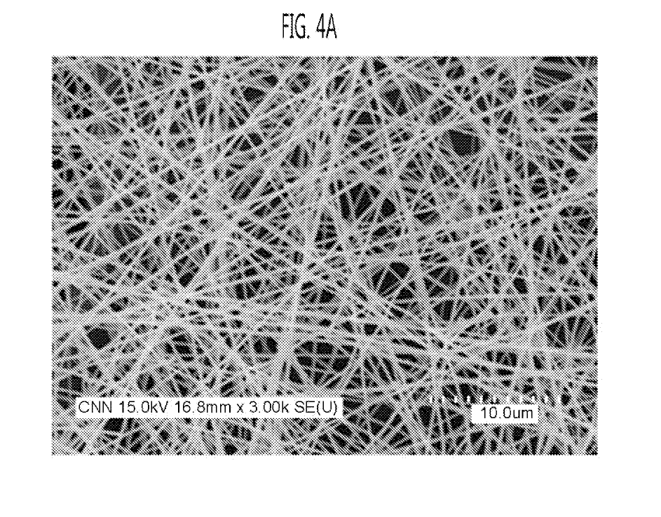

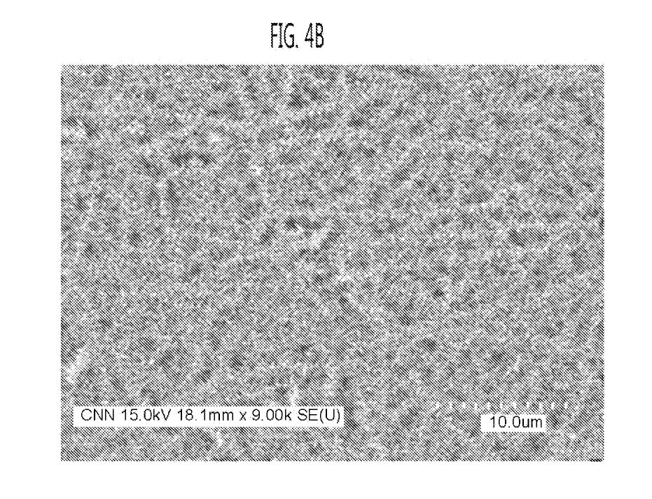

FIG. 4A is an SEM image of a surface of a semiconductor oxide ZnO nanofiber according to an exemplary embodiment of the present invention, and FIG. 4B is an SEM image of a surface of a semiconductor oxide ZnO nanofiber-nanorod hybrid structure according to an exemplary embodiment of the present invention.

FIG. 4A shows a fine structure of the ZnO nanofiber manufactured by thermally treating the ZnO/polymer composite fiber formed on a silicon (SiO₂/Si) substrate at 600° C. for 30 minutes, the ZnO nanofiber having a diameter of 30 to 70 nm.

Referring to FIG. 4A, the semiconductor oxide ZnO nanofiber may have a 1D structure to which a ZnO nano grain is linked.

Referring to FIG. 4B, it can be confirmed that the ZnO nanorod is well formed on the ZnO nanofiber, and thus it can be seen that the ZnO nanofiber-nanorod hybrid structure has an extremely large specific surface area.

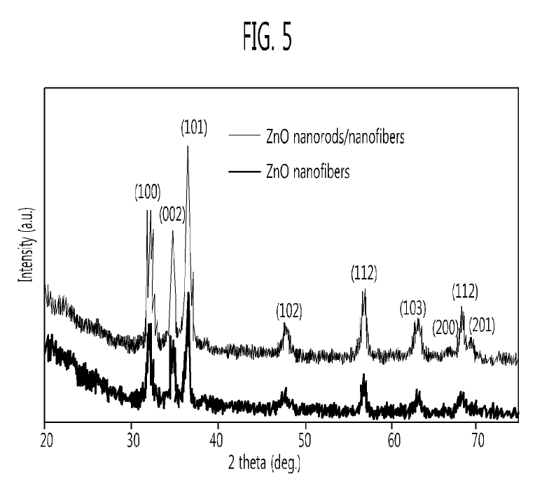

FIG. 5 is a graph of X-ray diffraction patterns of the semiconductor oxide ZnO nanofiber and the semiconductor oxide ZnO nanofiber-nanorod hybrid structure according to the exemplary embodiment of the present invention.

Referring to FIG. 5, as results of the X-ray diffraction test for the ZnO nanofiber and the ZnO nanofiber-nanorod hybrid structure, diffraction peaks (100), (002), (101) and (102) were observed, and it can be confirmed that a polycrystalline ZnO nanofiber was formed.

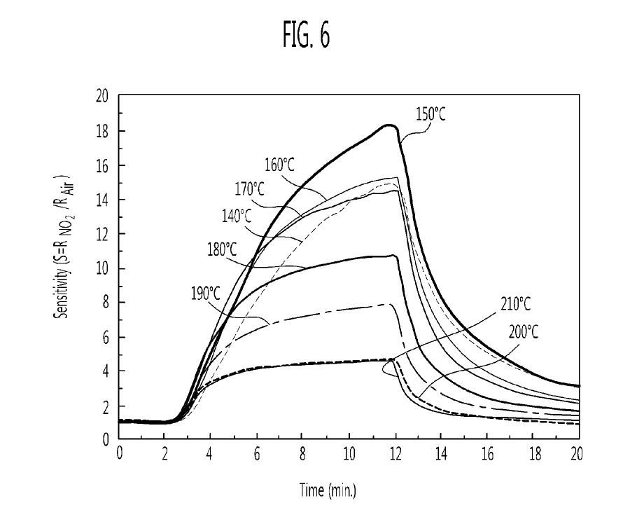

FIGS. 6 to 9 to be described below are graphs of evaluating gas reaction characteristics of the environmental gas sensor using the semiconductor oxide ZnO nanofiber-nanorod hybrid structure according to the exemplary embodiment of the present invention.

The ZnO nanofiber-nanorod hybrid structure was manufactured by forming the semiconductor oxide ZnO nanorod on the semiconductor oxide ZnO nanofiber by CBD as shown in FIG. 4B, and the environmental gas sensor was manufactured using such a ZnO nanofiber-nanorod hybrid structure.

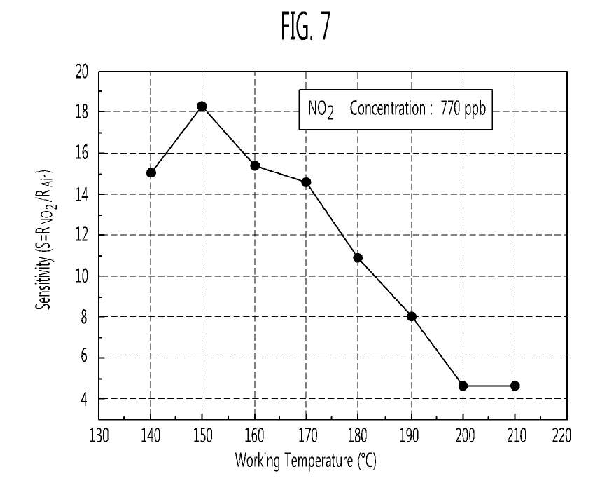

FIG. 6 is a time versus sensitivity graph according to a working temperature of a NO₂ gas sensor using the semiconductor oxide ZnO nanofiber-nanorod hybrid structure according to the exemplary embodiment of the present invention, and FIG. 7 is a graph of the change in sensitivity according to the working temperature of the NO₂ gas sensor using the semiconductor oxide ZnO nanofiber-nanorod hybrid structure according to the exemplary embodiment of the present invention.

In FIG. 6, sensitivity was shown by measuring resistance changes throughout temperatures ranging from 140 to 210° C. at a NO₂ gas concentration of 770 ppb. The sensitivity of the gas sensor is defined as a ratio of a resistance in a NO₂ gas atmosphere to a resistance in the air.

Referring to FIG. 6, until the working temperature reaches 150° C., the sensitivity is increased, and thus reaches the maximum level. After that, the sensitivity is gradually decreased, and thus reaches the minimum level at a working temperature of 200° C. or more (i.e., 200 or 210° C.).

At every working temperature, the sensitivity has no change for 2 to 3 minutes after the sensor is operated. However, afterwards, the sensitivity is gradually increased according to time, and reaches the maximum level at about 12 minutes after the sensor is operated. After that, it can be seen that the sensitivity is drastically decreased.

Referring to FIG. 7, it can be seen that the gas sensor exhibited the most excellent gas reaction characteristic at 150° C. when 770 ppb of the NO₂ gas was used as shown in FIG. 6.

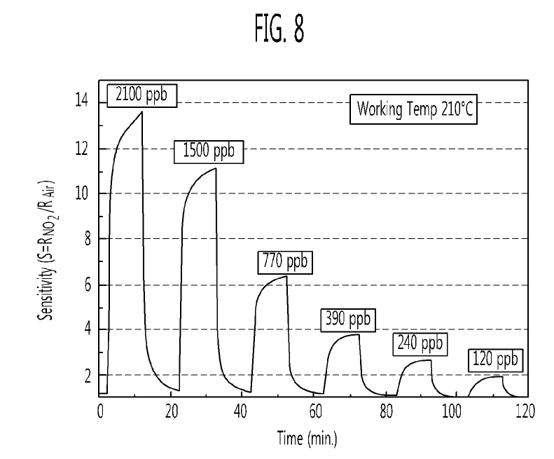

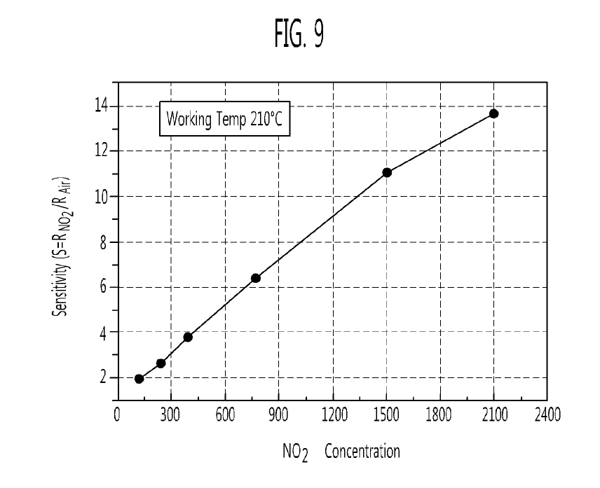

FIG. 8 is a time versus sensitivity graph according to a concentration of NO₂ gas of the NO₂ gas sensor using the semiconductor oxide ZnO nanofiber-nanorod hybrid structure according to the exemplary embodiment of the present invention, and FIG. 9 is a graph of the change in sensitivity according to a NO₂ gas concentration of the NO₂ gas sensor using the semiconductor oxide ZnO nanofiber-nanorod hybrid structure according to the exemplary embodiment of the present invention.

Referring to FIG. 8, while the concentration of the NO₂ gas was changed from 120 to 2100 ppb at a working temperature of 210° C., the change in sensitivity of the gas sensor was measured. Here, it can be seen that, as the concentration of the gas is increased, the sensitivity is also increased.

Referring to FIG. 9, it can be seen that the sensitivity is linearly increased according to the concentration of the NO₂ gas at a working temperature of 210° C.

Likewise, an environmental gas sensor using a semiconductor oxide nanofiber-nanorod hybrid structure according to the exemplary embodiment of the present invention as a gas sensing layer can have excellent characteristics of ultra high sensitivity, high selectivity, high responsiveness, long-term stability, and low power consumption by forming a semiconductor oxide nanorod having high sensitivity to a specific gas on a semiconductor oxide nanofiber to maximize a gas reactive specific surface area.

Thus, such an environmental gas sensor having excellent characteristics may be applied to a next generation ubiquitous sensor system and environment monitoring system requiring more accurate measurement and control of an environmentally harmful gas.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A semiconductor oxide nanofiber-nanorod hybrid structure, comprising:
a semiconductor oxide nanofiber; and
a semiconductor oxide nanorod formed on the semiconductor oxide nanofiber.

2. The structure of claim 1, wherein the semiconductor oxide nanofiber and the semiconductor oxide nanorod are formed of different semiconductor oxides.

3. The structure of claim 1, wherein the semiconductor oxide nanofiber is formed of one selected from the group consisting of ABO₃-type perovskite oxides (BaTiO₃, metal doped BaTiO₃, SrTiO₃, and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, CO₃O₄, and Al₂O₃.

4. The structure of claim 1, wherein the semiconductor oxide nanorod is formed of one selected from the group consisting of ABO₃-type perovskite oxides (BaTiO₃, metal doped BaTiO₃, SrTiO₃, and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, CO₃O₄, and Al₂O₃.

5. The structure of claim 1, wherein the semiconductor oxide nanofiber has a diameter of 1 to 100 nm.

6. The structure of claim 1, wherein the semiconductor oxide nanorod has a diameter of 1 to 100 nm and a length of 1 to 100 nm.

7. An environmental gas sensor, comprising:
an insulating substrate;
a metal electrode formed above the insulating substrate; and
a sensing layer formed of a semiconductor oxide nanofiber-nanorod hybrid structure above the metal electrode.

8. The sensor of claim 7, wherein the insulating substrate is a single crystalline oxide substrate, a ceramic substrate, a silicon semiconductor substrate, or a glass substrate.

9. The sensor of claim 8, wherein the insulating substrate is formed of a material selected from the group consisting of Al₂O₃, MgO, SrTiO₃, quartz, and SiO₂/Si.

10. The sensor of claim 7, further comprising an electrode pad formed of the same material as the metal electrode above the insulating substrate.

11. The sensor of claim 7, wherein the metal electrode is formed of at least one selected from the group consisting of Pt, Pd, Ag, Au, Ti, Cr, Al, Cu, Sn, and In.

12. The sensor of claim 7, wherein the semiconductor oxide nanofiber-nanorod hybrid structure constituting the sensing layer is formed of at least two selected from the group consisting of ABO₃-type perovskite oxides (BaTiO₃, metal doped BaTiO₃, SrTiO₃, and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, CO₃O₄, and Al₂O₃.

13. The sensor of claim 7, wherein the semiconductor oxide nanofiber is manufactured on the insulating substrate having the metal electrode by electrospinning, and the semiconductor oxide nanorod is manufactured by physical or chemical deposition.

14. The sensor of claim 7, wherein the semiconductor oxide nanofiber has a diameter of 1 to 100 nm.

15. The sensor of claim 7, wherein the semiconductor oxide nanorod has a diameter of 1 to 100 nm and a length of 1 to 100 nm.

16. The sensor of claim 7, further comprising a micro thin film heater formed at the same level as or on a bottom of the metal electrode.

17. A method of manufacturing a semiconductor oxide nanofiber-nanorod hybrid structure, comprising:
mixing a metal oxide precursor, a polymer and a solvent to prepare a composite solution;
spinning the composite solution by electrospinning and thermally treating the resulting solution to form a semiconductor oxide nanofiber; and
forming an oxide nanorod on the metal semiconductor oxide nanofiber by physical or chemical deposition.

18. The method of claim 17, wherein spinning the composite solution by electro spinning and thermally treating the resulting solution to form a semiconductor oxide nanofiber comprises:
spinning the composite solution by electrospinning to form an oxide/polymer composite fiber;
thermally treating the composite fiber to volatilize the solvent; and
thermally treating the thermally-treated composite fiber again at a high temperature to form a semiconductor oxide nanofiber.
